(19) United States
(12) Patent Application Publication
(10) Pub. No.: US 2005/0104759 A1
(43) Pub. Date: May 19, 2005

(54) Digital to analogue converter description

(76) Inventor: Adrianus Johannes Maria Van Tuijl, Eindhoven (NL)

Correspondence Address: U S Philips Corporaiton;Intellectual Property Department, P O Box 3001, Briarcliff Manor, NY, 10510, US

(21) Appl. No.: 10/498,759

(22) PCT Filed: Dec. 6, 2002
(86) PCT No.: PCT/IB02/05250

(30) Foreign Application Priority Data
Dec. 18, 2001 (EP) 01204951.6

(51) Int. Cl. H03M 1/66

(52) U.S. Cl. 341/144

(57) ABSTRACT

A circuit for analogue to digital or digital to analogue conversion comprising at least 2n matched current sources (40-1, 40-2, 40-n), where n is the resolution required of the conversion. Preferably more than 2n current sources (40-1, 40-2, 40-n) are used. The order in which the sources (40-1, 40-2, 40-n) are used may be changed in different samples. The current sources (40-1, 40-2, 40-n) may be replaced by one bit switched capacitor converters or by inverters connected to one end of a set of resistors, the other ends of which are connected to the virtual ground for an operational amplifier or alternatively to each other and arranged to directly generate the output voltage. According to one embodiment of the invention there is provided a sigma-delta analogue to digital converter comprising the circuit of the first aspect. A method is also provided which can be done by controlling each source with a duty cycle of M/2n, where n is the required resolution of the converter and M is the input word, and controlling different sources with a time shift. This allows an equal contribution from all the elements in one sample period with reduced switching and low sensitivity for time jitter.

The present invention relates to a digital to analogue converter.

The performance of digital to analogue converters depends upon the differences between the circuit elements employed since not all elements are common to the total signal flow. In particular, in practice, current sources have tolerance differences and resistors are not all identical.

One conventional technique for improving performance is dynamic element matching (DEM).

One form of DEM technique used in some digital to analogue converters is known as Data Weighted Averaging. A number of almost equal elements are interchanged such that the mean deviation is zero. The actual deviation appears as a noise component that is shaped such that its contribution in the signalband is low, e.g. first or second order noise shaping. The problem with this application is that the noise under certain boundary conditions can be mixed back into the signal band. An improvement would be seen if all the elements were interchanged in one sample period, but this can lead to very high switching frequencies and many switching edges that are sensitive to time jitter.

For example, for n bit resolution and input word M, then conventionally m current switches are switched on and 32-m sources are off. All sources are given equal weighting over time.

The present invention aims to have an equal contribution from all the elements in one sample period with reduced switching and low sensitivity for time jitter.

According to a second aspect of the present invention there is provided a circuit for signal conversion comprising at least 2ⁿ matched current sources, where n is the resolution required of the conversion.

Preferably some more than 2ⁿ current sources are used (with the number of clock phases accordingly adapted). The order in which the sources are used may be changed in different samples to reduce second order errors.

The converter is a digital to analogue converter that can be used in a sigma-delta analogue to digital converter. The current sources may be replaced by one bit switched capacitor converters or by inverters connected to one end of a set of resistors, the other ends of which are connected to the virtual ground of an operational amplifier or alternatively to each other and arranged to directly generate the output voltage.

According to one embodiment of the invention there is provided a sigma-delta analogue to digital converter loop comprising the circuit of the first aspect.

According to one aspect of the invention there is provided a method for digital to analogue conversion, the method comprising using 2ⁿ current sources or one bit switched capacitor convertors and switching on every source or convertor within each sampling period. This can be done by controlling each source or convertor with a duty cycle of M/2ⁿ, where n is the required resolution of the converter and M is the input word, and controlling different sources with a time shift. The time shift is typically 1/32 sampling period.

Preferably all clock pulses are made with different clock phases so that there is no correlation between the timing jitter of the pulses and the noise.

In addition, the order in which the sources or convertors are used may be changed for different samples.

According to a second aspect of the present invention there is provided a circuit for signal conversion comprising at least 2ⁿ matched current sources, where n is the resolution required of the conversion.

Preferably some more than 2ⁿ current sources are used (with the number of clock phases accordingly adapted). The order in which the sources are used may be changed in different samples to reduce second order errors.

The converter is a digital to analogue converter that can be used in a sigma-delta analogue to digital converter. The current sources may be replaced by one bit switched capacitor converters or by inverters connected to one end of a set of resistors, the other ends of which are connected to the virtual ground of an operational amplifier or alternatively to each other and arranged to directly generate the output voltage.

According to one embodiment of the invention there is provided a sigma-delta analogue to digital converter loop comprising the circuit of the first aspect.

For a better understanding of the present invention, and to show how the same may be carried into effect, reference will now be made, by way of example, to the accompanying drawings in which:

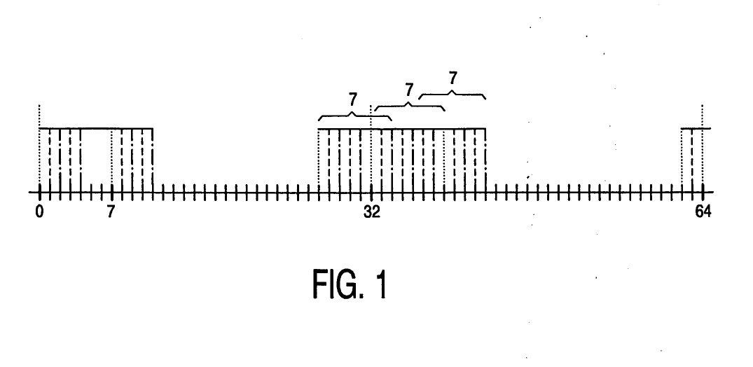

FIG. 1 is a timing diagram of two sample periods in a circuit in accordance with the present invention.

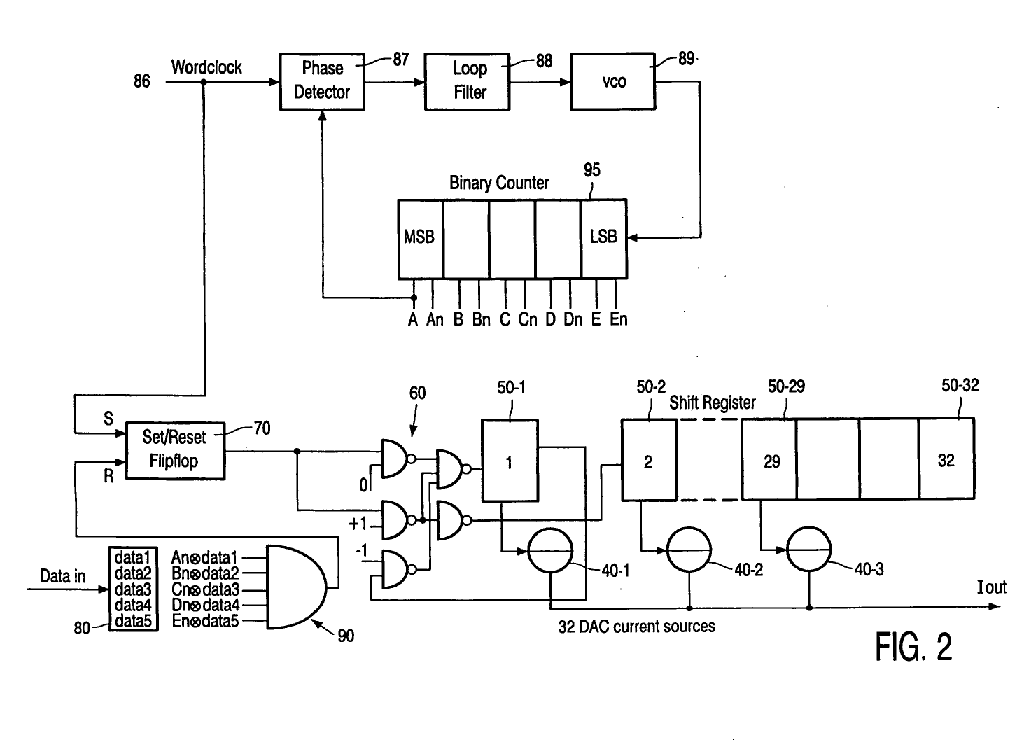

FIG. 2 is a circuit diagram of one embodiment of part of a circuit according to the present invention.

FIG. 1 illustrates two sample periods each divided into 32 clock phases. Each clock phase therefore corresponds with a time interval that is 1/32 of a sample period. Illustrated in FIG. 1 is a duty cycle of 7/32, i.e. each current source is switched on for 7/32 of the total sample period. During each new clock phase, i.e. each 1/32 of a sample period, one current source is switched on and another current source is switched off. Hence 7 current sources are on all of the time and all current sources are on for the same total time period because they all have the same duty cycle. Duty cycles that start at the end of a sample period continue in the next sample period. For a constant output signal this is equivalent to a representation at the beginning of the sample period because of the cyclic character of the duty cycle generation.

Consider five current sources, i.e. n=5, then 2ⁿ=32. Letting the input word (truncated at 5 bits) be m then traditionally m sources would be “on” and 32-m sources “off” and the arrangement would give all sources equal probability over time. The new invention controls each source to give it a duty cycle of m/32 so that every source comes “on” (and goes “off”) during each sampling period. The different sources are controlled with a time shift.

Additional current sources are preferable so as to minimise the effects of edges. Duty cycles of 0% and of 100% do not have edges and thus the additional current sources are used to introduce the same edges as for duty cycles between 0% and 100%. If extra sources are introduced, the same number of extra phases must also be brought in.

Preferably all pulses are made with different clock phases so that there is no correlation between the timing jitter of the different pulses. Hence the noise caused by the timing jitter ads only with the square root of the number of current sources.

A second order error arises if the time intervals are not exactly equal because of systematic differences in the timing of the different pulses. By changing the order in which the sources are used in different samples this error can be reduced.

The current sources may instead be one bit switched capacitor converters (in this case extra sources are not helpful in guaranteeing linearity for all duty cycles.

The current sources can also be replaced by inverters driving resistors with the other ends of the resistors connected to the virtual ground of an operational amplifier or to each other and directly generating the output voltage.

By way of example consider an audio analogue to digital converter (ADC) with a sample rate fs=44.1 kHz, assuming an oversampling of 64 times for interpolation and lowpass filtering so that the sample rate is 64*fs=2.8224 MHz.

When high order noise shaping is used a one bit representation can give enough resolution in the signal band but the level of the outband quantisation noise is very high. A one bit DAC is therefore very noise sensitive, particularly if the converter is of the switched current type, due to the time jitter on the edges. A higher resolution is hence aimed at reducing the step size of the edges but the higher resolution can only be useful if the accuracy is in the same order of magnitude as the dynamic range in the signal band. This also applies to ADCs.

To improve performance, for n bit resolution at least 2 to the power n matched current sources are used.

For 5 bit resolution therefore 32 matched current sources are used. The traditional operation of such a DAC would be: m current sources on and 32-m current sources off. All sources would be given equal probability over time.

According to this invention every source is on within each sampling period by controlling each source with a duty cycle of m/32 and introducing a time shift.

A circuit according to this invention is an improvement over an R-2R network since no new inaccuracies are introduced into the new circuitry, timing accuracy is not critical and Inter Symbol Interference (ISI) is zero.

The new circuit operates as a so-called “thermometer” DAC as distinct from a binary weighted DAC formed by R-2R networks.

FIG. 2 illustrates part of a circuit incorporating the teaching of this invention. This circuit is adapted for 5 bit resolution and thus has 32 DAC current sources of which three are shown in the FIG. 40-1, 40-2, 40-29. The current sources are supplied from the outputs of shift register stage 50-1, 50-2, 50-29 respectively.

The shift register input is supplied via gating logic 60, and a clocked flip-flop 70 by the 5 bit input data indicated at 80. Each data bit is combined with the inverted outputs an (most significant bit), Bn, Cn, Dn, En (least significant bit) of a binary counter 95, and is subsequently combined in AND gate 90. The resulting signal supplies the reset input R of flip-flop 70.

The set input 5 of flip-flop 70 is supplied from word clock 86. Clock 86 also feeds the binary counter 95 via a phase detector 87 a loop filter 88 and a VCO 89 which feeds the least significant bit E of the counter 95. The most significant bit of A of the counter 95 in turn feeds the phase detector 87 in a loop.

1. A method for digital to analogue conversion, the method comprising using 2ⁿ current sources (40-1, 40-2′″, 40-n) and, within each sampling period switching on and off every source.

2. A method according to claim 1 comprising controlling each source (40-1, 40-2′″, 40-n) with a duty cycle of M/2ⁿ, where n is the required resolution of the converter and M is the input word, and controlling different sources (40-1, 40-2, 40-n) with a time shift.

3. A method according to claim 1 wherein all clock pulses are made with different time equidistant clock phases.

4. A method according to claim 1 wherein the order in which the sources (40-1, 40-2, 40-n) are made is changed for different samples.

5. A method according to claim 1 wherein the order in which the sources (40-1, 40-2, 40-n) are used is changed in different sampling periods.

6. A method according to claim 1 wherein each of the current sources (40-1, 40-2′″, 40-n) comprise a one bit switched capacitor converter.

7. A circuit for signal conversion comprising at least 2ⁿ matched current sources (40-1, 40-2′″, 40-n) where n is the resolution required of the conversion.

8. A circuit according to claim 7 comprising more than 2ⁿ current sources (40-1, 40-2, 40-n).

9. A circuit according to claim 7 comprising a digital to analogue converter.

10. A circuit according to claim 7 comprising an analogue to digital converter.

11. A circuit according to claim 7 wherein the current sources comprise one bit itched capacitor converters.

12. A circuit according to claim 7 wherein the current sources (40-1, 40-2′″ 40-n) comprise inverters connected to one end of a set of resistors, the other ends of which are connected to the virtual ground for an operational amplifier or to each other and arranged to directly generate an output voltage.

13. A sigma-delta analogue to digital converter comprising the circuit of claim 7.
